(19) United States
(12) Patent Application Publication
(10) Pub. No.: US 2006/0221586 A1
(43) Pub. Date: Oct. 5, 2006

(54) Packaging substrate having adhesive-overflowing prevention structure

(75) Inventor: Hsin-Chen Yang, Taichung (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, Ltd., Taichung (TW)

(21) Appl. No.: 11/117,511

(22) Filed: Apr. 29, 2005

(30) Foreign Application Priority Data
Apr. 1, 2005 (TW) 94205141

(51) Int. Cl. H05K 1/18

(52) U.S. Cl. 361/782; 174/260; 257/724

(57) ABSTRACT

A packaging substrate includes an array of packaging units. Each packaging unit has a chip pad carrying a chip, a plurality of pins arranged around the chip pad and spaced from one another and the chip pad by an open space, an insulative member filling up the open space, passive components each connected between two pins, a bonding adhesive applied to the pins to which the passive components is connected to affix the connection between the passive components and the respective pins, and a plurality of overflow-preventive grooves respectively provided around the bonding adhesive at each of the pins to which the passive components are connected to prevent overflow of the bonding adhesive.

### BACKGROUND OF THE INVENTION

1. Field of the Invention

The present invention relates to a packaging substrate and more particularly, to such a packaging substrate, which has means to prevent overflow of bonding adhesive during installation of a passive component between pins.

2. Description of the Related Art

Following fast development of technology, it has become the market trend to provide electronic products having lighter, thinner, shorter and smaller characteristics. To fit this market trend, high-performance ICs are developed. From the application of early metal lead frame package technology to current flip chip technology, packaging substrate fabrication has been continuously improved. The invention pertains to improvement on QFN (Quad Flat No-lead) packaging substrate technology.

QFN semiconductor packaging technology has been intensively used in semiconductor foundries for years for packaging semiconductor products. Several QFN packaging technology based patents have been disclosed. Recently, there are manufacturers to secure pins to the packaging substrate by means of half-etching the packaging substrate to make openings among the pins of the lead frame and then filling up the openings with an insulative member to form a platform. The platform can is provided with a chip pad that carries a chip. Passive components or multiple electronic elements may be installed in the platform, increasing space utilization of the packaging substrate.

However, when installing a passive component in the aforesaid platform, a bonding adhesive is used to affix the passive component in position, keeping the passive component positively connected between two pins. During installation of the passive component, the bonding adhesive may be forced to overflow on the surface of the substrate, and a capillary effect may be produced, thereby causing a short circuit between the two pins.

### SUMMARY OF THE INVENTION

The present invention has been accomplished under the circumstances in view. It is one object of the present invention to provide a packaging substrate, which has an adhesive-overflowing prevention structure so as to prevent a short circuit happened during installation of a passive component between pins.

To achieve this object of the present invention, the packaging substrate comprises a plurality of packaging units arranged in an array. Each packaging unit comprises at least one chip pad on which a chip is carried; a plurality of pins arranged around the at least one chip pad and spaced from one another and the at least one chip pad by an open space; an insulative member filling up the open space; at least one passive component respectively connected between two of the pins; a bonding adhesive applied to the pins to which the at least one passive component is connected to affix the connection between the at least one passive component and the respective pins; wherein a plurality of overflow-preventive grooves are respectively provided around the bonding adhesive at each of the pins to which the at least one passive component is connected to prevent overflow of the bonding adhesive.

### BRIEF DESCRIPTION OF THE DRAWINGS

FIG. 1 is a top view of a packaging substrate according to a first preferred embodiment of the present invention.

FIG. 2 is a top view in an enlarged scale of one packaging unit of the packaging unit shown in FIG. 1.

FIG. 3 is a front view in section in an enlarged scale of a part of FIG. 2.

FIG. 4 is a top view of a part of one packaging unit of a packaging substrate according to a second preferred embodiment of the present invention.

### DETAILED DESCRIPTION OF THE INVENTION

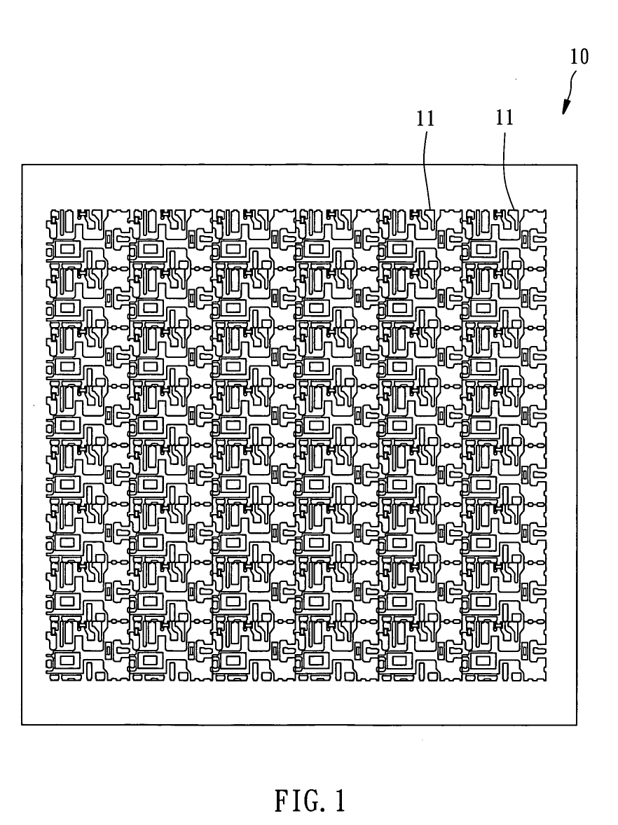

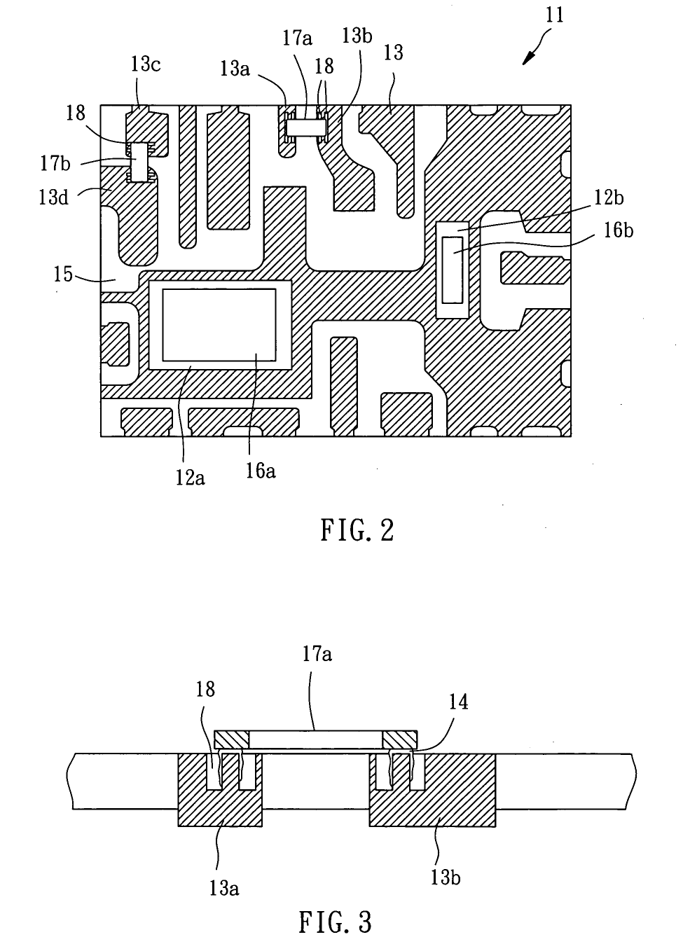

Referring to FIGS. 1-3, a packaging substrate in accordance with the first preferred embodiment of the present invention is shown comprising a plurality of packaging units 11 arranged in an array. The packaging units 11 have a flat, rectangular shape, each comprised of two chip pads 12a and 12b, a plurality of pins 13, an insulative member 15, two passive components 17a and 17b, and a plurality of overflow-preventive grooves 18.

The chip pads 12a and 12b each carry a chip 16a or 16b. The pins 13 are arranged along the border of the respective packaging unit 11 around the chip pads 12a. and 12b. The pins 13 are respectively spaced from the chip pad 12a and spaced from one another by openings. The insulative member 14 fills up the openings between the pins 13 and the chip pads 12a and 12b between each two adjacent pins 13, thereby forming with the pins 13 and the chip pads 12a and 12b a unitary platform. Further, a bonding adhesive 14 (for example, tin paste) is applied to four pins 13a, 13b, 13c, and 13d that are arranged in two pairs (only one pair of pins 13a and 13b is shown in FIG. 3). The two passive components 17a and 17b, which can be resistors, capacitors, or inductors, are respectively connected between the respective pair of pins 13a and 13b, or 13c and 13d and bonded to the bonding adhesive 14 at the respective pins. The overflow-preventive grooves 18 are straight grooves arranged in pairs respectively disposed at two sides of the bonding adhesive 14 at each of the pins 13a, 13b, 13c, and 13d.

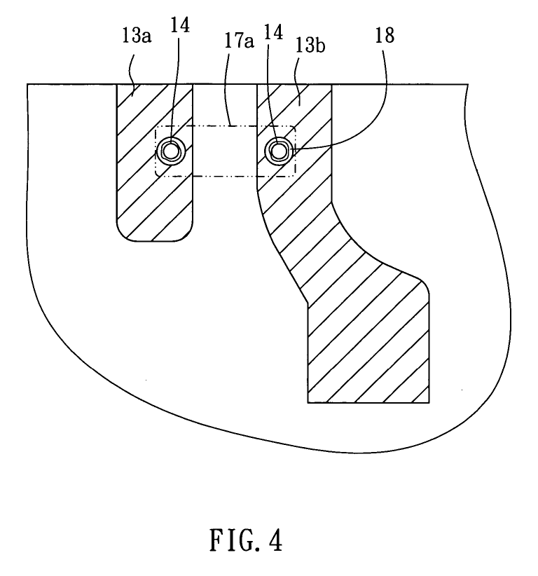

FIG. 4 shows a packaging substrate according to the second preferred embodiment of the present invention. This embodiment is substantially similar to the aforesaid first embodiment with the exception that the overflow-preventive grooves 18 are annular grooves respectively surrounding the bonding adhesive 14 at each of the pins 13a, 13b, 13c, and 13d.

By means of the arrangement of the aforesaid first and second embodiments of the present invention, the bonding adhesive will be guided into the overflow-preventive grooves when pressed by the passive components during the installation of the passive components, thereby preventing an overflow of the bonding adhesive on the surface of the substrate.

Although particular embodiments of the invention have been described in detail for purposes of illustration, various modifications and enhancements may be made without departing from the spirit and scope of the invention. Accordingly, the invention is not to be limited except as by the appended claims

What is claimed is:

1. A packaging substrate comprising a plurality of packaging units arranged in an array, said packaging units each comprising:
at least one chip pad on which a chip is carried;
a plurality of pins arranged around said at least one chip pad and spaced from one another and said at least one chip pad by an open space;
an insulative member filling up said open space;
at least one passive component respectively connected between two of said pins;
a bonding adhesive applied to the pins to which said at least one passive component is connected to affix the connection between said at least one passive component and the respective pins;
wherein said package substrate further comprises overflow-preventive grooves which are provided around the bonding adhesive at each of the pins to which said at least one passive component is connected to prevent overflow of said bonding adhesive.

2. The packaging substrate as claimed in claim 1, wherein said at least one passive component each is a resistor, a capacitor or an inductor.

3. The packaging substrate as claimed in claim 1, wherein said overflow-preventive grooves are straight grooves arranged in parallel at two sides of the bonding adhesive at each of the pins to which said at least one passive component is connected to prevent overflow of said bonding adhesive.

4. The packaging substrate as claimed in claim 1, wherein said overflow-preventive grooves are annular grooves respectively surrounding the bonding adhesive at each of the pins to which said at least one passive component is connected to prevent overflow of said bonding adhesive.

5. The packaging substrate as claimed in claim 1, wherein said bonding adhesive is tin paste.
